(19) United States
(12) Patent Application Publication
(10) Pub. No.: US 2010/0073346 A1
(43) Pub. Date: Mar. 25, 2010

(54) DISPLAY DEVICE AND DRIVING METHOD THEREOF

(75) Inventors: Ung-Gyu MIN, Namyangju-si (KR); Oh-Kyong KWON, Seoul (KR)

Correspondence Address: H.C. PARK & ASSOCIATES, PLC, 8500 LEESBURG PIKE, SUITE 7500, VIENNA, VA, 22182, US

(73) Assignees: Samsung Electronics Co., Ltd., Suwon-si (KR); IUCF-HYU (Industry-University Cooperation Foundation Hanyang University), Seoul (KR)

(21) Appl. No.: 12/393,423

(22) Filed: Feb. 26, 2009

(30) Foreign Application Priority Data
Sep. 24, 2008 (KR) 10-2008-0093765

(51) Int. Cl. G06F 3/038

(52) U.S. Cl. 345/211

(57) ABSTRACT

The present invention relates to a display device and a driving method thereof. The display device includes a plurality of display pixels, a plurality of data lines connected to the plurality of display pixels, and a plurality of sensing lines connected to the display pixels. Each display pixel includes a driving transistor having an input terminal, a control terminal, and an output terminal, a capacitor connected to the control terminal, a first switching transistor connected to the data line and the control terminal, a light emitting element receiving a driving current from the driving transistor and emitting light, a second switching transistor connected to the sensing lines and the output terminal, and a third switching transistor connected between the output terminal and the light-emitting element.

### CROSS REFERENCE TO RELATED APPLICATION

This application claims priority from and the benefit of Korean Patent Application No. 10-2008-0093765, filed on Sep. 24, 2008, which is hereby incorporated by reference for all purposes as if fully set forth herein.

### BACKGROUND OF THE INVENTION

1. Field of the Invention

The present invention relates to a display device and a driving method thereof, and particularly, to an organic light emitting device and a driving method thereof.

2. Discussion of the Background

A pixel of an organic light emitting device includes an organic light emitting element and a thin film transistor (TFT) for driving the organic light emitting element.

The thin film transistor is classified by type of an active layer into a polysilicon thin film transistor and an amorphous silicon thin film transistor. An organic light emitting device employing the amorphous silicon thin film transistor is advantageously suitable for a large screen and requires fewer manufacturing processes compared with an organic light emitting device employing a polysilicon thin film transistor. However, the organic light emitting device employing the amorphous silicon thin film transistor may have a problem of characteristic deterioration which is caused by the transition of a threshold voltage of the amorphous silicon thin film transistor because the amorphous silicon thin film transistor continuously applies current to the organic light emitting element. That is, although the same data voltage is applied, non-uniform current is applied to the organic light emitting element. Finally, the image quality of the organic light emitting device may be degraded.

Since current flows in the organic light emitting element for such a long time, a threshold voltage of the light emitting element is shifted. In a case of an n-channel thin film transistor, an organic light emitting element is disposed at a source side of a thin film transistor. Therefore, if a threshold voltage of the organic light emitting element is deteriorated, a voltage at the source side of the thin film transistor may be changed. Accordingly, a voltage between a source and a gate of a thin film transistor may be changed even though a uniform data voltage is applied to the gate of the thin film transistor. As a result, a non-uniform current flows in the organic light emitting element. This is another factor that may cause the degradation of the organic light emitting device.

Meanwhile, a hold type of flat panel display such as an organic light emitting device displays a predetermined image for a predetermined time, for example a time of one frame, regardless of a still image or a motion picture is displayed. For example, although an object continuously moves, the hold type of flat panel display displays the movement of the object discretely. That is, the hold type of flat panel display displays the object at a predetermined location at one frame and displays the object at another location at the next frame. Since a time of one frame is shorter than a time of a sustained afterimage, the movement of the object is shown to a viewer as a continuous motion even though the movement of the object is displayed discretely.

However, the discrete display method of the display device may cause blurring of a screen because a viewer's sight continuously moves along the movement path of the object when the viewer watches the object that continuously moves. For example, a display device displays one object in a location A at a first frame and displays the object in another location B at a second frame. A viewer's sight moves along an expected motion path of the object from the location A to the location B at the first frame. However, the object is not actually displayed at the middle position between the location A and the location B, only at the location A and the location B.

Finally, the luminance of the object shown to a viewer for the first frame is equivalent to integrating luminance values of pixels disposed between the location A and location B, that is, the average luminance of the object and background. Therefore, the object may be shown dimly.

Since the degree of blurring of an object in a hold type of display device is in proportion to a time of sustaining a displayed image of the display device, an impulse driving method has been introduced. The impulse driving method displays an image for a predetermined time in one frame and displays a black color for a remaining time.

### SUMMARY OF THE INVENTION

The present invention provides a display device and a driving method thereof having advantages of correcting threshold voltage degradation of a thin film transistor and an organic light emitting element in an organic light emitting device having an amorphous silicon thin film transistor and using an impulse driving method.

Additional features of the invention will be set forth in the description which follows, and in part will be apparent from the description, or may be learned by practice of the invention.

The present invention discloses a display device including a plurality of display pixels, a plurality of data lines connected to the plurality of display pixels, and a plurality of sensing lines connected to the display pixel. Each of the display pixels includes a driving transistor having an input terminal, a control terminal, and an output terminal, a capacitor connected to the control terminal, a first switching transistor connected to the data line and the control terminal, a light emitting element receiving a driving current from the driving transistor, a second switching transistor connected to the sensing lines and the output terminal, and a third switching transistor connected between the output terminal and the light-emitting element.

The present invention also discloses a driving method of a display device including a light-emitting element, a capacitor, and a driving transistor connected to the capacitor, the driving transistor having a control terminal, an input terminal, and an output terminal. The method includes connecting an anode terminal of the light-emitting element with a reference current source, sensing a voltage of the anode terminal of the light-emitting element, and calculating a transition degree of a threshold voltage of the light-emitting element by comparing a voltage of the anode terminal of the light-emitting element with a reference anode voltage.

The present invention also discloses a driving method of a display device including a sensing line and a display pixel having a light-emitting element, a capacitor, and a driving transistor connected to the capacitor, the driving transistor having a control terminal, an input terminal, and an output terminal. The method includes connecting the control terminal with a data voltage and connecting the sensing line with a precharge voltage, disconnecting the control terminal from the data voltage and connecting the light-emitting element with the output terminal, disconnecting the light-emitting element from the output terminal, sensing an anode voltage of the light-emitting element through the sensing line after the light-emitting element is disconnected from the output terminal, and calculating a transition degree of a threshold voltage of the light-emitting element by comparing an anode voltage of the light-emitting element with a reference anode voltage.

The present invention also discloses a driving method of a display device including a plurality of first display pixels each having a first light-emitting element, a first capacitor, and a first driving transistor connected to the first capacitor, the first driving transistor having a first control terminal, a first input terminal, and a first output terminal. The method includes connecting the first control terminal with a data voltage, disconnecting the first control terminal from the data voltage and connecting the first light-emitting element with the first output terminal, connecting the first light-emitting element with the first output terminal, applying a reference voltage that is lower than a threshold voltage of the first driving transistor to the first control terminal, connecting the first output electrode with a ground voltage and disconnecting the first output electrode from the ground voltage, sensing a voltage of the first output electrode, and calculating a threshold voltage of the first driving transistor based on a voltage of the first output electrode.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a block diagram of an organic light emitting device according to an exemplary embodiment of the present invention.

FIG. 2 is an equivalent circuit diagram of a pixel with a data driver and a signal controller in an organic light emitting device according to an exemplary embodiment of the present invention.

FIG. 3 is a block diagram of an image signal corrector of an organic light emitting device according to an exemplary embodiment of the present invention.

FIG. 4 shows a waveform showing a driving signal applied to pixels of one row in an organic light emitting device according to an exemplary embodiment of the present invention.

FIG. 5, FIG. 6, FIG. 7, FIG. 8, and FIG. 9 are equivalent circuit diagrams showing one pixel in each period shown in FIG. 4.

FIG. 10 and FIG. 11 are circuit diagrams showing a pixel of an organic light emitting device before turning on the organic light emitting device according to an exemplary embodiment of the present invention.

FIG. 12 is a waveform showing a driving signal applied to pixels of one row in an organic light emitting device according to another exemplary embodiment of the present invention.

FIG. 13, FIG. 14, FIG. 15, and FIG. 16 are equivalent circuit diagrams showing one pixel in each period of FIG. 12.

FIG. 17 is an equivalent circuit diagram of a pixel in an organic light emitting device with a data driver and a signal controller according to another exemplary embodiment of the present invention.

FIG. 18 is a circuit diagram of a pixel for calculating a threshold voltage of a driving transistor in an organic light emitting device of FIG. 17.

FIG. 19 is a circuit diagram showing one pixel before turning on the organic light emitting device of FIG. 17.

FIG. 20 is a circuit diagram of a pixel for calculating a threshold voltage of an organic light emitting element of FIG. 17.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

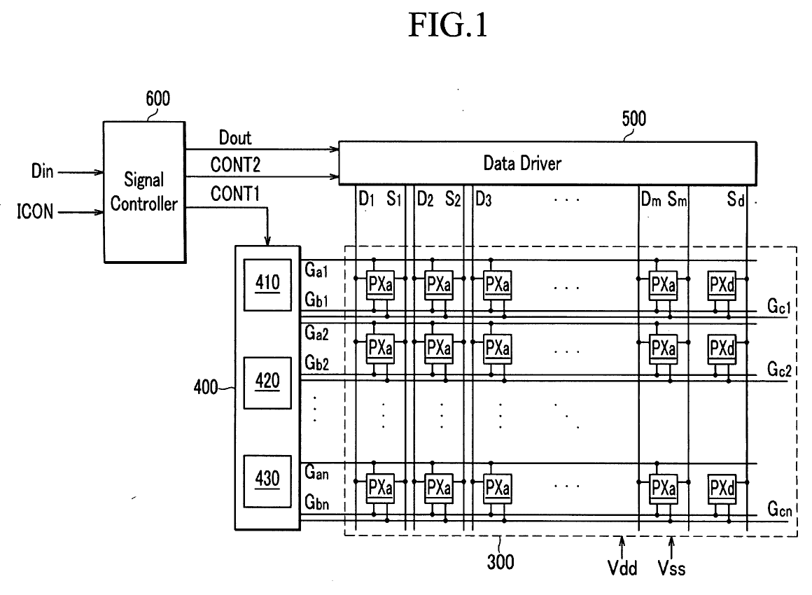

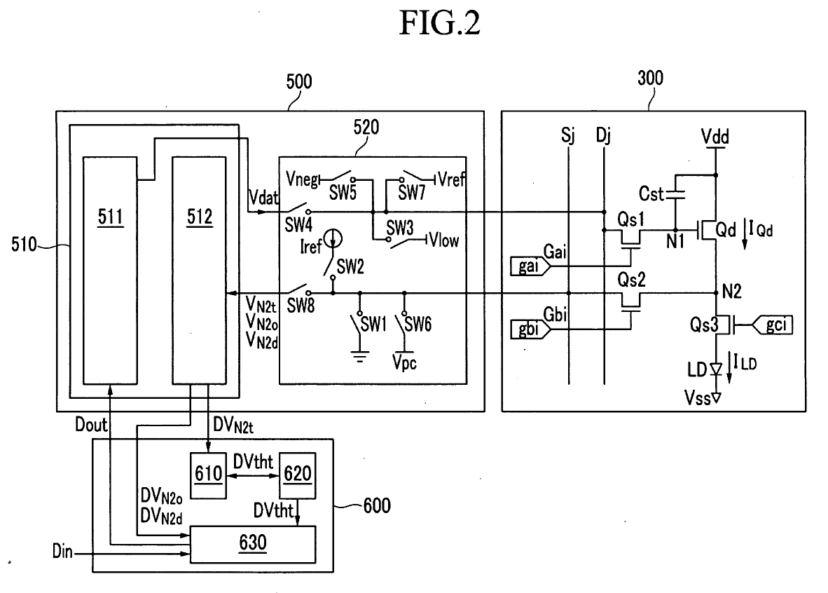

With reference to FIG. 1 and FIG. 2, an organic light emitting device according to an exemplary embodiment of the present invention will be described.

FIG. 1 is a block diagram of an organic light emitting device according to an exemplary embodiment of the present invention, and FIG. 2 is an equivalent circuit diagram of a pixel with a data driver and a signal controller in an organic light emitting device according to an exemplary embodiment of the present invention.

Referring to FIG. 1, the organic light emitting device according to an exemplary embodiment of the present invention includes a display panel 300, a scanning driver 400, a data driver 500, and a signal controller 600.

The display panel 300 includes a plurality of signal lines Gₐ₁-Gₐₙ, G_{b1}-G_{bn}, G_{c1}-G_{cn}, S₁-Sₘ, S_{d}, and D₁-Dₘ, a plurality of voltage lines (not shown), and a plurality of display pixels PXa and dummy pixels PXd connected to the signal lines and voltage lines and arranged basically in a matrix.

The signal lines Gₐ₁-Gₐₙ, G_{b1}-G_{bn}, G_{c1}-G_{cn}, S₁-Sₘ, S_{d}, and D₁-Dₘ include a plurality of first scanning signal lines Gₐ₁-Gₐₙ for transferring a first scanning signal, a plurality of second scanning signal lines G_{b1}-G_{bn} for transferring a second scanning signal, a plurality of third scanning signal lines G_{c1}-G_{cn} for transferring a third scanning signal, a plurality of sensing lines S₁-Sₘ and S_{d} for transferring a sensed data signal, and a plurality of data lines D₁-Dₘ for transferring an image data signal. The first scanning signal lines Gₐ₁-Gₐₙ, the second scanning signal lines G_{b1}-G_{bn}, and the third scanning signal lines G_{c1}-G_{cn} extend in a row direction to run substantially parallel to each other. The sensing lines S₁-Sₘ and S_{d} and the data lines D₁-Dₘ extend in a column direction to run substantially parallel to each other.

The display pixels PXa are pixels that substantially display an image and are connected to the first to third scanning signal lines Gₐ₁-Gₐₙ, G_{b1}-G_{bn}, and G_{c1}-G_{cn}, the sensing lines S₁-Sₘ, and the data lines D₁-Dₘ. On the contrary, the dummy pixels PXd are pixels that do not display an image, and are connected to the second scanning signal lines G_{b1}-G_{bn}, the third scanning signal lines G_{c1}-G_{cn}, and the sensing lines S₁-Sₘ.

The voltage lines include a driving voltage line (not shown) for transferring a driving voltage.

As shown in FIG. 2, each of the display pixels includes an organic light emitting element LD, a driving transistor Qd, a capacitor Cst, and first, second, and third switching transistors Qs1 -Qs3.

The driving transistor Qd includes an output terminal, an input terminal, and a control terminal. In the driving transistor Qd, the control terminal is connected to the capacitor Cst and the first switching transistor Qs1 at a contact N1, the input terminal is connected to the driving voltage Vdd, and the output terminal is connected to the second and third switching transistors Qs2 and Qs3 at a contact N2.

One end of the capacitor Cst is connected to the driving transistor Qd at the contact N1, and the other end is connected to the driving voltage Vdd.

The first switching transistor Qs1 operates in response to the first scanning signal gₐᵢ, the second switching transistor Qs2 operates in response to the second scanning signal g_{bi}, and the third switching transistor Qs3 operates in response to the third scanning signal g_{ci}.

The first switching transistor Qs1 is connected between the data line Dj and the contact N1, the second switching transistor Qs2 is connected between the sensing line Sj and the contact N2, and the third switching transistor Qs3 is connected between the organic light emitting element LD and the contact N2.

The driving transistor Qd and the first to third switching transistors Qs1, Qs2, and Qs3 are n-channel electric field effect transistors. For example, the electric field effect transistor may be a thin film transistor TFT and include amorphous silicon.

An anode and a cathode of the organic light emitting element LD are connected to the third switching transistor Qs3 and the common voltage Vss, respectively. The organic light emitting element LD displays images by changing the intensity of emitted light according to the amplitude of the current I_{LD} applied from the driving transistor Qd through the third switching transistor Qs3. The amplitude of the current I_{LD} depends on a magnitude of a voltage between the control terminal and the input terminal of the driving transistor Qd.

Meanwhile, the dummy pixels PXd are formed at one side of the display panel 300. Like the display pixels PXa, the dummy pixels PXd may include an organic light emitting element LD, a driving transistor Qd, a capacitor Cst, and first, second, and third switching transistors Qs1-Qs3.

Referring to FIG. 1 again, the scanning driver 400 includes a first scanning driver 410 connected to the first scanning signal lines Gₐ₁-Gₐₙ of the display panel 300, a second scanning driver 420 connected to the second scanning signal lines G_{b1}-G_{bn}, and a third scanning driver 430 connected to the third scanning signal lines G_{c1}-G_{cn}. The first to third scanning drivers 410, 420, and 430 apply a first scanning signal gₐᵢ, a second scanning signal g_{bi}, and a third scanning signal g_{ci}, each of which is formed of a combination of a high voltage Von and a low voltage Voff, to the first scanning signal lines Gₐ₁-Gₐₙ, the second scanning signal lines G_{b1}-G_{bn}, and the third scanning signal lines G_{c1}-G_{cn}, respectively.

The high voltage Von can turn on the first to third switching transistors Qs1-3, and the low voltage Voff can turn off the first to third switching transistors Qs1-3.

Referring to FIG. 2, the data driver 500 includes a basic circuit portion 510 and a switching circuit portion 520.

The basic circuit portion 510 includes a digital-to-analog converter 511 and an analog-to-digital converter 512.

The digital-to-analog converter 511 receives a digital output image signal Dout for displaying pixels of each row, converts the received digital output image Dout to an analog data voltage Vdat, and applies the analog data voltage Vdat to the data lines D₁-Dₘ. The analog-to-digital converter 512 receives sensed data signals V_{N2t}, V_{N2o}, and V_{N2d} from each of the display pixels PXa through the sensing lines Sj, and converts and outputs the received sensed data signals to digital values DV_{N2t}, DV_{N2o}, and DV_{N2d}.

The switching circuit portion 520 includes a first switch SW1 for connecting and disconnecting the second switching transistor Qs2 and the ground voltage, a second switch SW2 for connecting and disconnecting the second switching transistor Qs2 and a reference current source Iref, a third switch SW3 for connecting and disconnecting the data lines Dj and the first reference voltage Vlow, a fourth switch SW4 for connecting and disconnecting the data lines Dj and the digital-to-analog converter 511, a fifth switch SW5 for connecting and disconnecting the first switching transistor Qs1 and a reverse bias voltage Vneg, a sixth switch SW6 for connecting and disconnecting the sensing lines Sj and a precharge voltage Vpc, a seventh switch SW7 for connecting and disconnecting the first switching transistor Qs1 and the second reference voltage Vref, and an eighth switch SW8 for connecting and disconnecting the sensing line Sj and the analog-to-digital converter 512.

The signal controller 600 controls the operations of the scanning driver 400, the data driver 500, and a light emission driver (not shown). The signal controller 600 also receives an input image signal Din, corrects the input image signal Din according to the characteristic of the driving transistor Qd and the characteristic of the organic light emitting element LD, and outputs an output image signal Dout.

The signal controller 600 includes a first calculator 610, a first frame memory 620, and an image signal corrector 630.

The first calculator 610 calculates a threshold voltage DVtht of the driving transistor Qd based on the first sensed data signal DV_{N2t} sensed at the display pixels PXa.

The first frame memory 620 receives and stores the threshold voltage DVtht of the driving transistor Qd included in each of the display pixels PXa from the first calculator 610.

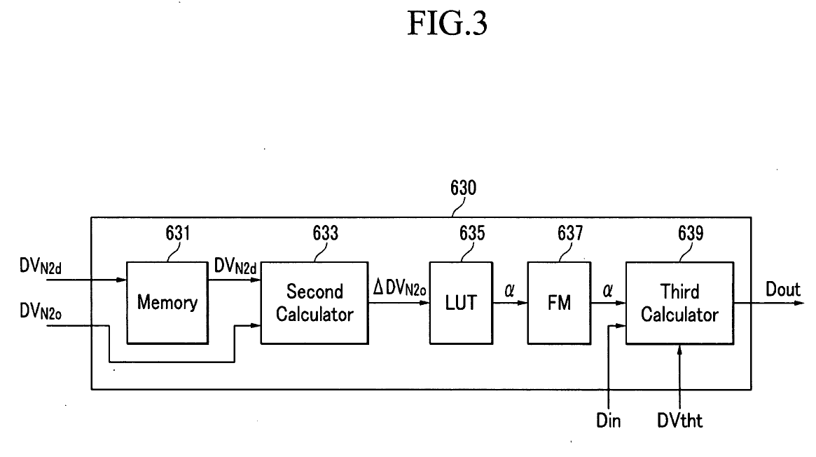

The image signal corrector 630 corrects an input image signal Din and outputs the corrected input image signal Din as an output image signal Dout. Referring to FIG. 3, the image signal corrector 630 includes a memory 631, a second calculator 633, a lookup table 635, a second frame memory 637, and a third calculator 639.

The memory 631 receives the second sensed data signal V_{N2d} from the dummy pixels PXd through the analog-to-digital converter 512 in a digital form DV_{N2d}, and stores the received second sensed data signal as a digital value DV_{N2d}.

The second calculator 633 receives the third sensed data signal V_{N2o} from the display pixels PXa through the analog-to-digital converter 512 in a digital form DV_{N2o}, calculates a difference ΔDV_{N2d} from the second sensed data signal DV_{N2d}, and outputs the difference ΔDV_{N2d}.

The lookup table 635 stores a degradation factor α according to the calculated difference ΔDV_{N2d} between the second sensed data signal DV_{N2d} and the third sensed data signal DV_{N2o}. The degradation factor α denotes a degree of degradation of the organic light emitting element LD of a display pixel PXa. The lookup table 635 may store a degradation factor α that indicates 100% luminance when the difference ΔDV_{N2d} is 0, and has a value that decreases as an exponential function as the difference ΔDV_{N2d} increases.

The second frame memory 637 stores degradation factors α of each display pixel PXa and outputs the stored degradation factors.

The third calculator 639 corrects an input image signal Din based on the degradation factor α of a corresponding display pixel PXa and the threshold voltage DVtht of the driving transistor Qd, and outputs an output image signal Dout.

Alternatively, the memory 631 may store not only the second sensed data signal DV_{N2d} but also the third sensed data signal DV_{N2o}, and output the stored signals to the second calculator 633. Also, the lookup table 635 may store the degradation factors α according to the second sensed data signal DV_{N2d} and the third sensed data signal DV_{N2o} without the second calculator 633.

The drivers 400, 500, and 600 may be directly mounted on the display panel 300 in the form of at least one IC chip, may be mounted on a flexible printed circuit film (not shown) to be attached to the display panel 300 in the form of a tape carrier package (TCP), or may be mounted on an additional printed circuit board (PCB) (not shown). The drivers 400, 500, and 600 may be integrated with the display panel 300 with the signal lines Gₐ₁-Gₐₙ, G_{b1}-G_{bn}, G_{c1}-G_{cn}, S₁-Sₘ, S_{d}, and D₁-Dₘ and the transistors Qs1-Qs3 and Qd. Also, the driver 400, 500, and 600 may be integrated into a single chip. In this case, at least one of the drivers 400, 500, and 600 or at least one circuit that form the drivers 400, 500, and 600 may be provided outside the single chip.

Now, a method for correcting an input image signal according to characteristics of a driving transistor and an organic light emitting element of an organic light emitting device will be described.

Equation 1 expresses a current I_{Qd} that flows in the driving thin film transistor Qd in FIG. 2.

$${I}_{QD} = \frac{1}{2} μ {C}_{OX} \frac{W}{L} {( Vgs - \vert Vtht \vert )}^{2} \qquad ( Equation 1 )$$

In Equation 1, μ denotes field effect mobility, C_{OX} denotes capacity of a gate insulating layer, W denotes a channel width of a driving transistor Qd, L is a channel length of the driving transistor Qd, and Vgs denotes a voltage difference between a control terminal and an output terminal of the driving transistor Qd.

Equation 2 expresses the maximum current Imax by each gray with correction according to the characteristic deviation of the driving transistor Qd and the degradation of the organic light emitting element LD in Equation 1.

$$\frac{100}{100 - α} \times \frac{corresponding gray}{{2}^{n} - 1} \times I max = \frac{1}{2} μ {C}_{ox} \frac{W}{L} {( Vg - Vs - \vert Vtht \vert )}^{2} \qquad ( Equation 2 )$$

In Equation 2, n denotes the number of bits of the input image signal.

Equation 3 expresses a voltage Vg applied to a control terminal of the driving transistor Qd from Equation 2.

$$Vg - Vs + \vert Vtht \vert + \sqrt{\frac{100}{100 - α}} \times \sqrt{\frac{corresponding gray}{{2}^{n} - 1}} \times \sqrt{\frac{2 I max}{μ {C}_{ox} \frac{W}{L}}} \qquad ( Equation 3 )$$

Therefore, the voltage Vg applied to the control terminal of the driving transistor Qd, that is, the data voltage Vdat of each display pixel PXa, can be calculated based on the degradation factor α of the organic light emitting element LD, the field effect mobility μ of the driving transistor Qd, and the threshold voltage Vtht. That is, the data voltage Vdat applied to each of the pixels PXa is determined from Equation 3. Since the data voltage Vdat is an analog voltage that is selected according to the output image signal Dout outputted from the signal controller 600, the input image signal Din is corrected to the output image signal Dout to be suitable for Equation 3.

The organic light emitting device according to an exemplary embodiment of the present invention determines the voltage Vg to be applied to the control terminal of the driving transistor Qd by calculating the threshold voltage Vtht of the driving transistor Qd and the degradation factor α of the organic light emitting element LD and using a predetermined average value μ as the field effect mobility of the driving transistor Qd.

Now, a method for calculating a threshold voltage Vtht of a driving transistor Qd and a degradation factor α of an organic light emitting element LD in an organic light emitting device according to an exemplary embodiment of the present invention will be described.

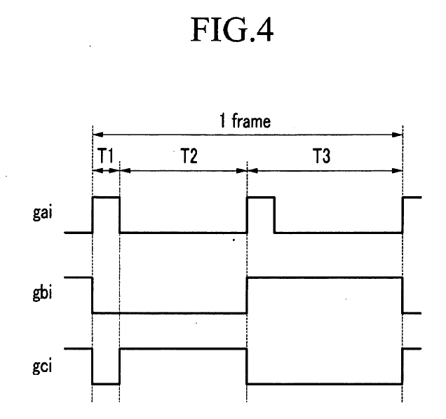

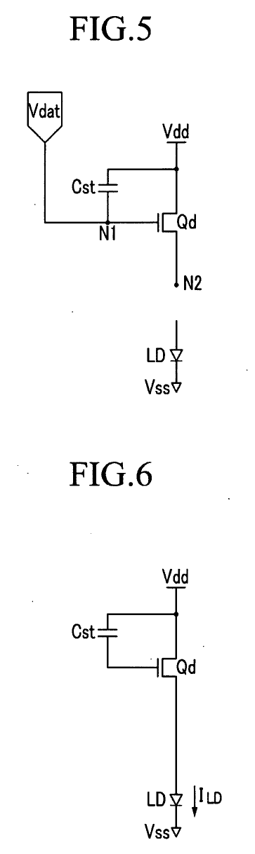

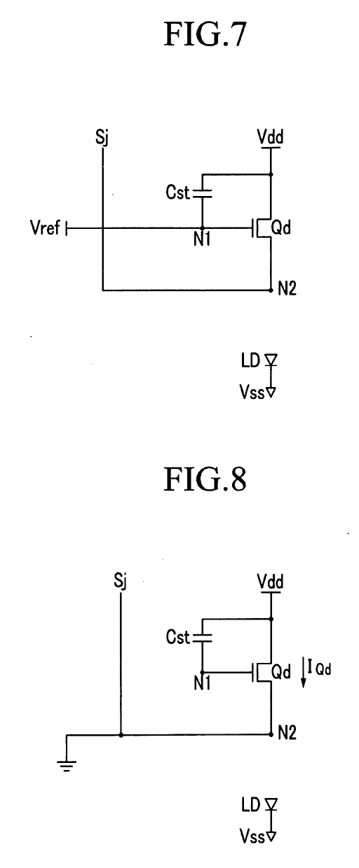

Hereinafter, display operation of an organic light emitting device and a method for calculating a threshold voltage of a driving transistor will be described with reference to FIG. 4, FIG. 5, FIG. 6, FIGS. 7, and 8.

FIG. 4 is a waveform showing a driving signal applied to pixels of one row in an organic light emitting device according to an exemplary embodiment of the present invention, and FIG. 5, FIG. 6, FIG. 7, and FIG. 8 are equivalent circuit diagrams of a pixel in each period of FIG. 4.

The signal controller 600 receives an input image signal Din and an input control signal ICON for controlling display of the input image signal Din from an external graphics controller (not shown). The input image signal Din includes luminance information of each display pixel PXa, and the luminance has a predetermined number of grays, such as 1024(=2¹⁰), 256(=2⁸), or 64(=2⁶). For example, the input control signal ICON may be a vertical synchronization signal, a horizontal synchronizing signal, a main clock signal, or a data enable signal.

The signal controller 600 corrects the input image signal Din based on the input image signal Din and the input control signal ICON, and generates a scanning control signal CONT1 and a data control signal CONT2. The signal controller 600 transmits the scanning control signal CONT1 to the scanning driver 400 and transmits the data control signal CONT2 and the output image signal Dout to the data driver 500.

The scanning control signal CONT1 includes three control signals for controlling the first to third scanning drivers 410, 420, and 430. For example, the scanning control signal CONT1 includes a scanning start signal STV for instructing scanning start, at least one of clock signals for controlling an output period for outputting a high voltage Von, and an output enable signal OE for limiting a time of sustaining the high voltage Von.

The data control signal CONT2 includes a horizontal synchronization start signal for informing beginning of transmission of the digital image signal Dout for display pixels PXa of a row, a load signal for applying an analog data voltage to the data lines D₁-Dₘ, and a data clock signal HCLK.

The scanning driver 400 converts the first to third scanning signals to a high voltage Von or a low voltage Voff according to the scanning control signal CONT1 from the signal controller 600.

The data driver 500, particularly the basic circuit portion 510, receives digital output image signals Dout for display pixels PXa of each row, converts the digital output image signals Dout to analog data voltages Vdat, and applies the analog data voltages Vdat to the data lines D₁-Dₘ in response to the data control signal CONT2 from the signal controller 600. The data driver 500 outputs a data voltage Vdat for display pixels PXa of one row for one horizontal period 1 H.

Hereinafter, operation of a predetermined pixel row, for example an i-th row, will be described.

Referring to FIG. 4, the scanning driver 400 converts the first scanning signal gₐᵢ applied to the first scanning signal line Gₐᵢ to a high voltage Von, and converts the second scanning signal g_{bi} applied to the second scanning signal line G_{bi} and the third scanning signal g_{ci} applied to the third scanning signal line G_{ci} to a low voltage Voff in response to the scanning control signal CONT1 from the signal controller 600.

Then, the first switching transistor Qs1 is turned on and the second and third switching transistors Qs2 and Qs3 are turned off, as shown in FIG. 5.

When the first switching transistor Qs1 is turned on, the data voltage Vdat is applied to the contact N1, and a voltage difference between the contact N1 and the contact N2 is stored in a capacitor Cst. As a result, the organic light emitting element LD does not emit light because the third switching transistor Qs3 is turned off even though the driving transistor Qd is turned on and current flows thereto. This is referred to as a data writing period T1.

As shown in FIG. 4, the scanning driver 400 changes the first scanning signal gₐᵢ applied to the first scanning signal line Gₐᵢ to a low voltage Voff, sustains the second scanning signal g_{bi} applied to the second scanning signal line G_{bi} as the low voltage Voff, and converts the third scanning signal g_{ci} applied to the third scanning signal line G_{ci} to the high voltage Von according to the scanning control signal CONT1 from the signal controller 600.

Then, the first and second switching transistors Qs1 and Qs2 are turned off and the third switching transistor Qs3 is turned on, as shown in FIG. 6. At this moment, an output terminal of the driving transistor Qd is connected to the light-emitting element LD, the driving transistor Qd applies an output current I_{LD}, which is controlled by the voltage difference Vgs between the control terminal and the output terminal of the driving transistor Qd, to the organic light emitting element LD, and the organic light emitting element emits light. This is an emission period T2. The voltage charged in the capacitor Cst is continuously sustained for one frame even though the first scanning signal gₐᵢ is changed to a low voltage Voff and the first switching transistor Qs1 is turned off. Therefore, a control terminal voltage of the driving transistor Qd is uniformly sustained.

Then, the scanning driver 400 converts the first and second scanning signals gₐᵢ and g_{bi} applied to the first and second scanning signal lines Gₐᵢ and G_{bi} to a high voltage Von, and converts the third scanning signal g_{ci} applied to the third scanning signal line G_{ci} to a low voltage Voff. Then, the seventh switch SW7 is turned on.

The first and second switching transistors Qs1 and Qs2 are then turned on, and the third switching transistor Qs3 is turned off, as shown in FIG. 7. The contact point N1, that is, the control terminal of the driving transistor Qd, is connected to the second reference voltage Vref. The second reference voltage Vref has a higher value than the threshold voltage Vtht of the driving transistor Qd. Since the third switching transistor Qs3 is turned off, the organic light emitting element LD stops emitting light, and the display pixels PXa become a black state.

Then, the first scanning signal gₐᵢ applied to the first scanning signal line Gₐᵢ is changed to a low voltage Voff, the second scanning signal g_{bi} applied to the second scanning signal line G_{bi} is sustained as the high voltage Von, the third scanning signal g_{ci} applied to the third scanning signal line G_{ci} is sustained as a low voltage Voff, and the first switch SW1 is turned on. As shown in FIG. 8, the organic light emitting element LD sustains not emitting light, and the contact N2 is connected to the ground voltage. Then, if the first switch SW1 is turned off, a voltage of the contact N2 gradually increases from the ground voltage and converges to a predetermined voltage value when the current I_{Qd} of the driving transistor Qd becomes 0. Herein, the voltage of the contact N2 is sensed through the sensing lines Sj as the first sensed data signal V_{N2t}. The first sensed data signal V_{N2t} is converted into a digital value DV_{N2t} at the analog-to-digital converter 512. The first calculator 610 receives the first sensed data signal DV_{N2t} and outputs the threshold voltage DVtht of the driving transistor Qd. This is referred to as a sensing period T3.

Equation 4 expresses the threshold voltage DVtht of the driving transistor Qd.

|Vtht|=Vref−V_{N2t} (Equation 4)

For convenience, the equation is expressed as an analog voltage value.

The sum of the data writing period T1 and the emission period T2 may be identical to the length of the sensing period T3, and the sum of the three periods T1, T2, and T3 is substantially identical to one frame.

Meanwhile, while a predetermined display pixel PXa senses the first sensed data signal V_{N2t} in the sensing period T3, the other display pixels PXa disposed in the same pixel row perform a different operation. This will be described in detail below.

FIG. 9 is an equivalent circuit diagram of a display pixel shown in FIG. 5 to FIG. 8 in a sensing period of FIG. 4 in an organic light emitting device according to an exemplary embodiment of the present invention.

Like the sensing period T3 of FIG. 4, the scanning driver 400 changes the first and second scanning signals gₐᵢ, and g_{bi} applied to the first and second scanning signal lines Gₐᵢ, and G_{bi} to a high voltage Von, and changes the third scanning signal g_{ci} applied to the third scanning signal line G_{ci} to a low voltage Voff.

As shown in FIG. 9, the first and second switching transistors Qs1 and Qs2 are turned on, and the third switching transistor Qs3 is turned off. Also, the fifth switch SW5 is turned on. When the third switching transistor Qs3 is turned off, the organic light emitting element LD stops emitting light, and the display pixels PXa become a black state. At this moment, the contact N1, that is, the control terminal of the driving transistor Qd, is applied with a reverse bias voltage Vneg. A voltage difference between the contact N1 and the contact N2 is applied to the capacitor Cst.

Then, the scanning driver 400 changes the first scanning signal gₐᵢ applied to the first scanning signal line Gₐᵢ to a low voltage Voff, sustains the second scanning signal g_{bi} applied to the second scanning signal line G_{bi} as the low voltage Voff, and sustains the third scanning signal g_{ci} applied to the third scanning signal line G_{ci} as the low voltage Voff. Then, the first switching transistor Qs1 is turned off, and the second and third switching transistors Qs2 and Qs3 are sustained as turned-off. Since a voltage charged in the capacitor Cst is continuously sustained even though the first scanning signal gₐᵢ is changed to the low voltage Voff and the first switching transistor Qs1 is turned off, the control terminal voltage of the driving transistor Qd is uniformly sustained.

The reverse bias voltage Vneg has an opposite polarity to that of the data voltage Vdat. For example, if the data voltage Vdat has a positive polarity, the reverse bias voltage Vneg has a negative polarity. A level of the reverse bias voltage Vneg may differ according to a magnitude of the data voltage Vdat, a type of organic light emitting element OLED, characteristics thereof, or design elements. For example, the level of the reverse bias voltage Vneg may be set to have an absolute value that is larger than a maximum value of the data voltage Vdat, or about an average value.

If the reverse bias voltage Vneg is applied to the control terminal of the driving transistor Qd, the degradation of the driving transistor Qd is prevented. That is, if the data voltage Vdat of a predetermined polarity is continuously applied to the control terminal of the driving transistor Qd for a long time, the threshold voltage thereof is shifted and the image quality is degraded as time goes on. However, a reverse bias voltage Vneg is applied to the control terminal of the driving transistor Qd while the display pixels PXa are in the black state in the present exemplary embodiment. Therefore, it is possible to suppress the transition of the threshold voltage by resolving stress that is caused by the data voltage Vdat applied during the data writing period T1.

If a predetermined display pixel in one pixel row performs a sensing operation and other display pixels receive a reverse bias voltage Vneg while the display pixels PXa are in the black state as described above, it is possible to correct the data voltage Vdat according to a transition degree of the threshold voltage of the driving transistor Qd and suppress the transition of the threshold voltage of the driving transistor Qd.

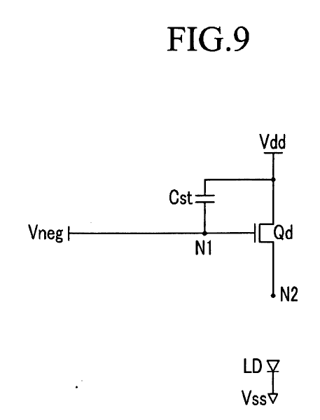

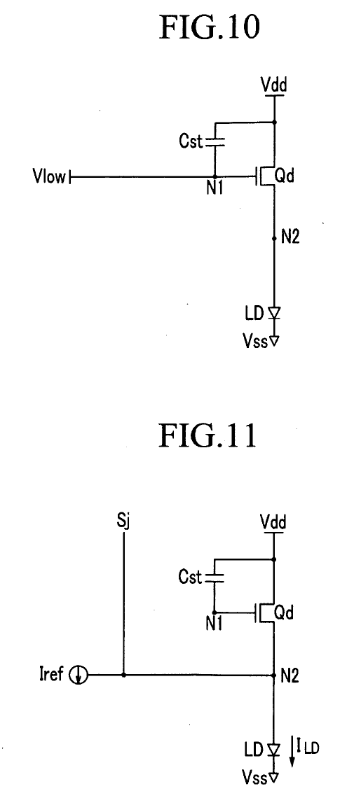

A method for calculating a threshold voltage Vtht of a driving transistor Qd of each display pixel PXa in an organic light emitting device according to an exemplary embodiment of the present invention will now be described with reference to FIG. 10 and FIG. 11 with FIG. 1 and FIG. 2.

FIG. 10 and FIG. 11 are equivalent circuit diagrams of a display pixel before a display operation is performed in an organic light emitting device according to an exemplary embodiment of the present invention, that is, before a user turns on the organic light emitting device.

If the first scanning signal gₐᵢ and the third scanning signal g_{ci} are shifted to a high voltage Von, if the second scanning signal g_{bi} is shifted to a low voltage Voff, and if the third switch SW3 is turned on, the first and third switching transistors Qs1 and Qs3 are turned on and the second switching transistor Qs2 is turned off, as shown in FIG. 4. Here, a voltage Vlow that is lower than the threshold voltage Vtht of the driving transistor Qd is applied to the control terminal of the driving transistor Qd. As a result, the driving transistor Qd is turned off, current does not flow, and the light emitting element LD does not emit light.

After that, the first scanning signal gₐᵢ is shifted to a low voltage Voff, the second scanning signal g_{bi} is shifted to a high voltage Von, the third scanning signal g_{ci} is sustained as a high voltage Von, and the second switch SW2 is turned on. Then, the second and third switching transistors Qs2 and Qs3 become turned on, and the first switching transistor Qs1 becomes turned off as shown in FIG. 11. Then, current flows into the organic light emitting element LD by the reference current source Iref, and the organic light emitting element LD emits light. Herein, a voltage of the contact N2 is sensed along the sensing lines Sj. Then, if the eighth switch SW8 is turned on, the voltage of the contact N2 is input to the analog-to-digital converter 512 as the third sensed data signal V_{N2o}. The analog-to-digital converter 512 converts the third sensed data signal V_{N2o} to a digital value DV_{N2o} and outputs the digital value.

Hereinafter, a display pixel PXa actually performing a display operation will be described with reference to FIG. 10 and FIG. 11. While the display pixel PXa senses the third sensed data signal V_{N2o}, a dummy pixel PXd senses the second sensed data signal V_{N2d}. A circuit and operation of the dummy pixel PXd are identical to those described with FIG. 10 and FIG. 11, and the second sensed data signal V_{N2d} is a voltage of the contact N2 in FIG. 11. The second sensed data signal V_{N2d} is output as a digital value DV_{N2d} through the analog-to-digital converter 512.

The second and third sensed data signals DV_{N2d} and DV_{N2o} are input to the image signal corrector 630 of the signal controller 600.

The degradation factor α can be calculated by sensing the second sensed data signal DV_{N2d} at the display pixel PXa, sensing the third sensed data signal DV_{N2d} at the dummy pixel PXd, comparing second and third sensed data signals DV_{N2d} and DV_{N2o}, and determining how much an organic light emitting element LD of the display pixel PXa is degraded compared with an organic light emitting element LD of the dummy pixel PXd based on the comparison result. As described above, the degradation factor α is calculated through the memory 631, the second calculator 623, and the lookup table 635, and stored in the second frame memory 637 of FIG. 3.

The processes described with FIG. 10 and FIG. 11 may be performed before a user turns on the organic light emitting device. Therefore, it is possible to determine the degradation degree before the organic light emitting device is used.

If the transition degree of the threshold voltage Vtht of the organic light emitting element LD is determined based on another reference, it may be difficult to accurately determine the transition degree because the other reference is a value without regard to environmental variation where a display device is used, such as a temperature variation. However, the organic light emitting device according to the present embodiment can accurately determine the transition degree of the threshold voltage Vtho of the organic light emitting element LD in consideration of the environmental variation where the display device is used, such as temperature variation, because the organic light emitting device according to the present embodiment uses the organic light emitting element LD of the dummy pixel PXd in the same display device as a reference to determine the transition degree of the threshold voltage Vtho of the organic light emitting element LD.

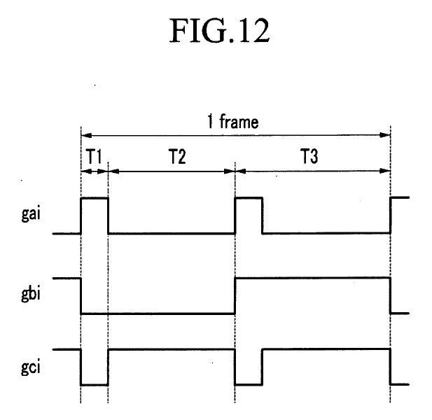

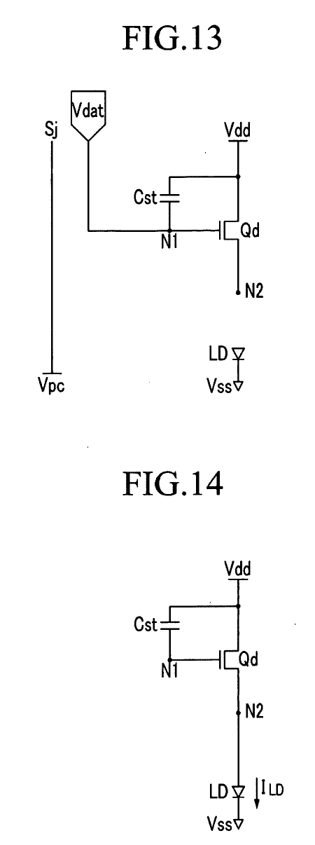

Hereinafter, a method for calculating a degradation factor α of an organic light emitting element LD according to another exemplary embodiment of the present invention will be described with reference to FIG. 12, FIG. 13, FIG. 14, FIG. 15, and FIG. 16.

FIG. 12 is a waveform of a driving signal applied to pixels of one row in an organic light emitting device according to another exemplary embodiment of the present invention, and FIG. 13, FIG. 14, and FIG. 15 are equivalent circuit diagrams of a pixel in each period of FIG. 12.

Referring to FIG. 12, the scanning driver 400 changes the first scanning signal gₐᵢ applied to the first scanning signal line Gₐᵢ to a high voltage Von, changes the second scanning signal g_{bi} applied to the second scanning signal line G_{bi} to a low voltage Voff, and changes the third scanning signal g_{ci} applied to the third scanning signal line G_{ci} to a low voltage according to the scanning control signal CONT1 from the signal controller 600. Then, the scanning driver 400 turns on the sixth switch SW6.

Then, the first switching transistor Qs1 becomes turned on, and the second and third switching transistors Qs2 and Qs3 become turned off as shown in FIG. 13.

If the first switching transistor Qs1 is turned on, a data voltage Vdat is applied to the contact N1, and a voltage difference between the contacts N1 and N2 is stored in the capacitor Cst. Therefore, the driving transistor Qd becomes turned on, and current flows into it. However, the organic light emitting element LD does not emit light because the third switching transistor Qs3 is turned off. This is referred to as a data writing period T1.

Herein, the sensing lines Sj are connected to the precharge voltage Vpc and pre-charged. The precharge voltage Vpc is lower than the threshold voltage of the organic light emitting element LD.

Then, the scanning driver 400 changes the first scanning signal gₐᵢ applied to the first scanning signal line Gₐᵢ to a low voltage Voff, sustains the second scanning signal g_{bi} applied to the second scanning signal line G_{bi} as a low voltage Voff, and changes the third scanning signal g_{ci} applied to the third scanning signal line G_{ci} to a high voltage Von according to the scanning control signal CONT1 from the signal controller 600, as shown in FIG. 12.

Then, the first and second switching transistors Qs1 and Qs2 become turned off, and the third switching transistor Qs3 becomes turned on as shown in FIG. 14. Herein, the output terminal of the driving transistor Qd is connected to the light-emitting element LD, the driving transistor Qd flows output current I_{LD} to the organic light emitting element LD, and the organic light emitting element emits light. The output current I_{LD} is controlled by a voltage difference Vgs between the control terminal and the output terminal of the driving transistor Qd. This is referred as a emission period T2.

A voltage charged in the capacitor Cst is continuously sustained for one frame even though the first scanning signal gₐᵢ is changed to a low voltage Voff and the first switching transistor Qs1 becomes turned off. Therefore, the control terminal voltage of the driving transistor Qd is uniformly sustained.

At this time, the sensing line Sj is pre-charged with a precharge voltage Vpc that is lower than the threshold voltage Vtho of the organic light emitting element LD in the data writing period T1. Therefore, the voltage of the sensing line Sj is sustained lower than the threshold voltage Vtht of the light emitting element LD in the emission period T2 even though the sensing line Sj is isolated. If the voltage of the sensing line Sj is higher than an anode voltage of the organic light emitting element LD, it is impossible to sustain desired luminance because current flows into the sensing line Sj, not to the light-emitting element LD.

Then, the scanning driver 400 changes the first and second scanning signals gₐᵢ and g_{bi} applied to the first and second scanning signal lines Gₐᵢ and G_{bi} to a high voltage Von, and changes the third scanning signal g_{ci} to the third scanning signal line G_{ci} to a low voltage Voff. Then, the third switch SW3 is turned on.

The first and second switching transistors Qs1 and Qs2 then become turned on and the third switching transistor Qs3 becomes turned off as shown in FIG. 15. Then, the contact N1, that is, the control terminal of the driving transistor Qd, is connected to the first reference voltage Vlow. The first reference voltage Vlow is significantly lower than the threshold voltage Vtht of the driving transistor Qd. Since the third switching transistor Qs3 is turned off, the organic light emitting element LD stops emitting light, and the display pixels PXa become the black state.

Then, the scanning driver 400 changes the first scanning signal gₐᵢ applied to the first scanning signal line Gₐᵢ to a low voltage Voff, sustains the second scanning signal g_{bi} applied to the second scanning signal line G_{bi} as a high voltage Von, and changes the third scanning signal g_{ci} applied to the third scanning signal line G_{ci} to a high voltage Von. Since the first reference voltage Vlow that is lower than the threshold voltage Vtht is applied to the control terminal of the driving transistor Qd, the driving transistor Qd becomes turned off, and the organic light emitting element LD sustains a state of not emitting light. Since the voltage of the contact N2, that is, a voltage of an anode terminal of the organic light emitting element LD, decreases, the voltage of the anode terminal of the organic light emitting element LD is converged to a predetermined value after a predetermined time. This voltage is referred to as the threshold voltage of the organic light emitting element LD. At this time, the eighth switch SW8 is turned on and the second switching transistor Qs2 sustains the turn-on state. Therefore, the threshold voltage of the organic light emitting element LD, that is, the voltage V_{N2o} of contact N2, is input to the analog-to-digital converter 512 as the third sensed data signal. The analog-to-digital converter 512 converts the third sensed data signal V_{N2o} to a digital value DV_{N2o}, and outputs the digital value. This is referred to as a sensing period T3.

Here, a voltage of the contact N2 is sensed through the sensing line Sj as the first sensed data signal V_{N2t}. The first sensed data signal V_{N2t} is converted to a digital value DV_{N2t} at the analog-to-digital converter 512. Then, the first calculator 610 receives the first sensed data signal DV_{N2t} and outputs the threshold voltage DVtht of the driving transistor Qd. This is referred to as a sensing period T3.

Hereinafter, a display pixel PXa actually performing a display operation will be described with reference to FIG. 12, FIG. 13, FIG. 14, FIG. 15, and FIG. 16. The dummy pixel PXd senses the threshold voltage of the organic light emitting element LD as the second sensed data signal V_{N2d} while the display pixel PXa senses the third sensed data signal V_{N2o}. However, the dummy pixel PXd only includes the sensing period T3 without the data writing period T1 and the emission period T2. A circuit and operation of the dummy pixel in the sensing period T3 are identical to those described with respect to FIG. 15 and FIG. 16. The second sensed data signal V_{N2d} is also output as a digital value DV_{N2d} through the analog-to-digital converter 512.

The second and third sensed data signals DV_{N2d} and DV_{N2o} are input to the image signal corrector 630 of the signal controller 600. A method of calculating a degradation factor α in the image signal corrector 630 is identical to the description of the memory 631, the second calculator 623, the lookup table 635, and the second frame memory 637.

In the present exemplary embodiment, it is possible to calculate the degradation factor α of the organic light emitting element LD during the sensor period T3 at a predetermined frame for a predetermined display pixel PX, to correct an image signal using previously calculated values such as the threshold voltage Vtht of the driving transistor Qd, to calculate the threshold voltage Vtht of the driving transistor Qd in the sensing period T3 at a predetermined frame, and to correct the image signal using the previously calculated values such as the degradation factor α of the organic light emitting element LD.

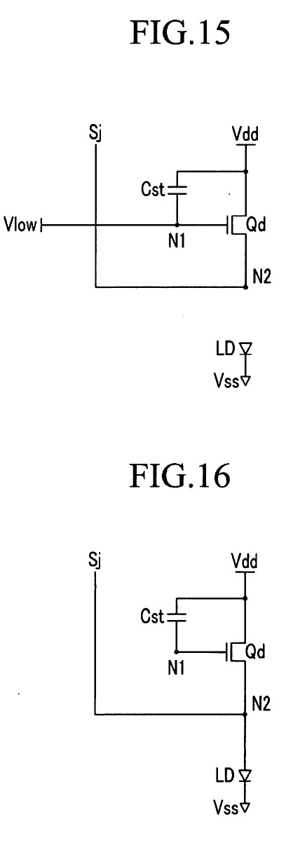

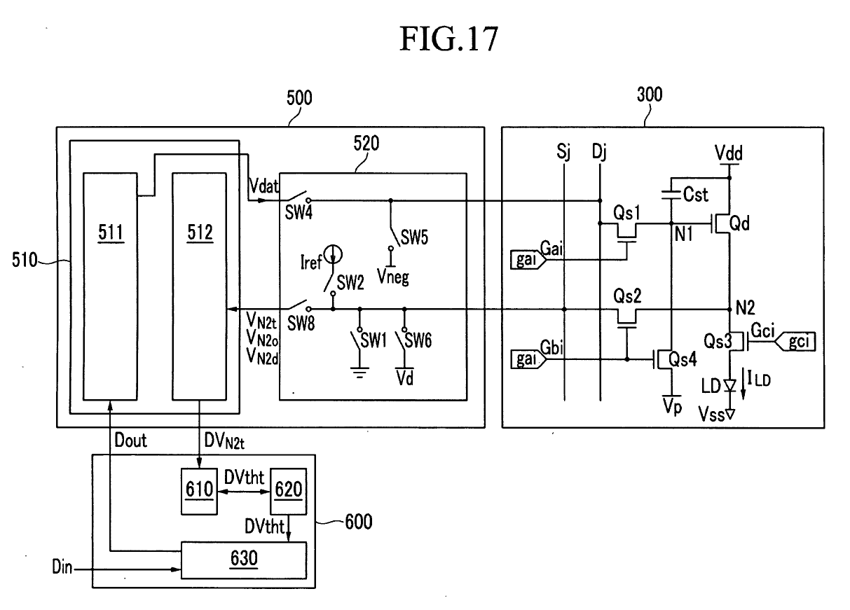

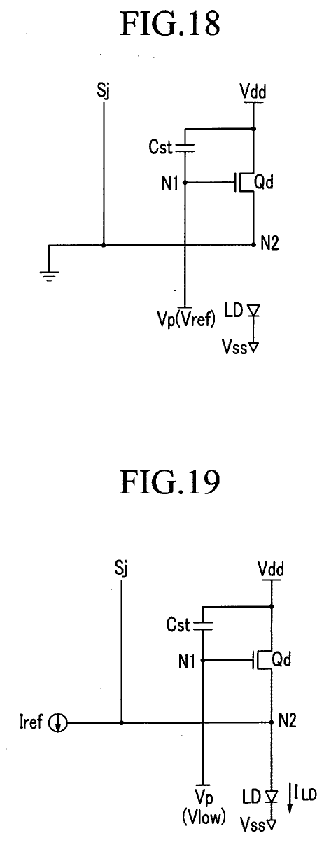

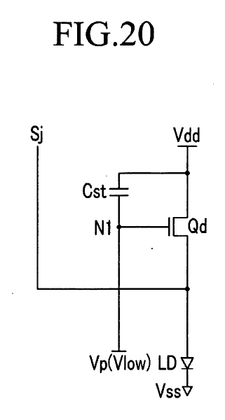

Hereinafter, an organic light emitting device according to another exemplary embodiment of the present invention will be described with reference to FIG. 17, FIG. 18, FIG. 19, and FIG. 20.

FIG. 17 is an equivalent circuit diagram showing a data driver and a signal controller according to another exemplary embodiment of the present invention.

Referring to FIG. 17, the organic light emitting device according to the present exemplary embodiment includes a display panel 300, a scanning driver (not shown), a data driver 500, and a signal controller 600. The display panel 300 includes a plurality of signal lines G_{a1-G}ₐₙ, G_{b1}-G_{bn}, G_{c1}-G_{cn}, S₁-Sₘ, S_{d}, and D₁-Dₘ, first to third switching transistors Qs1-3 connected to the signal lines, a driving transistor Qd, and an organic light emitting element LD.

Unlike the organic light emitting device of FIG. 2, the organic light emitting device of FIG. 17 further includes a fourth switching transistor Qs4 operating in response to the second scanning signal gₐᵢ. The fourth switching transistor Qs4 is connected to the contact N1 and a control voltage Vp.

Also, the organic light emitting device of FIG. 17 does not include third and seventh switches SW3 and SW7, unlike the organic light emitting device of FIG. 2.

Hereinafter, a method for calculating a degradation factor α of the organic light emitting element LD and a threshold voltage Vtht of the driving transistor in the organic light emitting device of FIG. 17 will be described.

Also, a method for calculating the threshold voltage Vtht of the driving transistor Qd in the organic light emitting device of FIG. 17 will be described with reference to FIG. 18.

FIG. 18 is a circuit diagram of a pixel of an organic light emitting device of FIG. 17 in a sensing period T3.

Referring to FIG. 18, the first and third switching transistors Qs1 and Qs3 become turned off, and the second and fourth switching transistors Qs2 and Qs4 become turned on. Therefore, the contact N1 is connected to a power source Vp. Here, the power source Vp is applied with the second reference voltage Vref. Since the third switching transistor Qs3 is turned off, the organic light emitting element LD does not emit light. At this moment, if the first switch SW1 is turned off after turning on, it is possible to calculate the threshold voltage Vtht of the driving transistor Qd as described in FIG. 10.

Meanwhile, while a predetermined display pixel PXa calculates the threshold voltage Vtht of the driving transistor Qd, organic light emitting elements LD of the other display pixels PXa in the same pixel row stop emitting light and become a black state. At this time, the fifth switch SW5 is turned on. That is, a reverse bias voltage is applied to the control terminal of the driving transistor Qd. A voltage difference between the contact N1 and the contact N2 is applied to the capacitor Cst. Since it is identical to those described in FIG. 9, detailed description thereof is omitted.

A method for calculating a degradation factor α of an organic light emitting element LD in the organic light emitting device of FIG. 17 will now be described.

FIG. 19 is a circuit diagram of a pixel in an organic light emitting device of FIG. 17.

As shown in FIG. 19, the first to fourth switching transistors Qs1 to Qs4 are turned on and the second switch SW2 is turned on. Then, the contact N1 is connected to a power source Vp. At this moment, a low voltage Vlow is applied to the power source Vp. Therefore, the driving transistor Qd is turned off because a voltage that is lower than the threshold voltage Vtht is applied to the control terminal of the driving transistor Qd. At this moment, the voltage V_{N2o} of the contact N2 is sensed because corresponding current I_{LD} flows into the organic light emitting element LD by a reference current source Iref as in FIG. 5. At the dummy pixel PXd, it is also possible to calculate a degradation factor α by measuring a voltage V_{N2d} of the contact N2 when the reference current source Iref is connected and comparing the voltage V_{N2d} with the voltage V_{N2o} of the display pixel PXa.

Hereinafter, a method for calculating a degradation factor α of an organic light emitting element LD in an organic light emitting device of FIG. 17 according to another embodiment of the present invention will be described with reference to FIG. 20.

FIG. 20 is a circuit diagram of a pixel of an organic light emitting device of FIG. 17 in a sensing period T3.

Referring to FIG. 20, the first switching transistor Qs1 is turned off, and the second to fourth switching transistors Qs2-4 are turned on. Therefore, the contact N1 is connected to the power source Vp. Here, the power source Vp is applied with the first reference voltage Vlow. Therefore, the driving transistor Qd sustains as a turn-off state by applying the first reference voltage Vlow to the control terminal of the driving transistor Qd. The degradation factor α of the organic light emitting element LD can be calculated as described above with respect to FIG. 16.

As described above, the organic light emitting device of FIG. 17 applies one of the first and second reference voltages Vlow and Vref to the contact N1 through the fourth switching transistor Qs4. When one of the first and second reference voltages Vlow and Vref is applied to the contact N1 through the first switching transistor Qs1, it is required to turn off the first switching transistor Qs1 after applying one of the first and second reference voltages Vlow and Vref. Then, the sensed data signals V_{N2t}, V_{N2o}, and V_{N2d} cannot be accurately sensed because the voltage of the contact N1 is influenced by peripheral voltages after the first switching transistor Qs1 is turned off. On the contrary, the organic light emitting device of FIG. 17 sustains the fourth switching transistor Qs4 to be turned on after applying one of the first and second reference voltages Vlow and Vref to the contact N1 without turning off the fourth switching transistor Qs4. Therefore, it is possible to stably sustain the voltage of the contact N1. Therefore, the sensed data signals V_{N2t}, V_{N2o}, and V_{N2d} can be accurately sensed.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A display device, comprising:
a plurality of display pixels;
a plurality of data lines connected to the plurality of display pixels; and
a plurality of sensing lines connected to the display pixel,
wherein each display pixel comprises:
a driving transistor comprising an input terminal, a control terminal, and an output terminal;
a capacitor connected to the control terminal;
a first switching transistor connected to the data line and the control terminal;
a light emitting element to receive a driving current from the driving transistor;
a second switching transistor connected to the sensing lines and the output terminal; and
a third switching transistor connected between the output terminal and the light-emitting element.

2. The display device of claim 1, further comprising:
a signal controller to output an output image signal by correcting an input image signal based on transition of a threshold voltage of the light-emitting element with time; and
a data driver to convert an image data voltage based on the output image signal and apply the image data voltage to the data line.

3. The display device of claim 2, further comprising a plurality of dummy pixels not displaying images,
wherein the transition of the threshold voltage of the light-emitting element is determined by comparing an anode voltage of a light emitting element of the display pixel with an anode voltage of a light emitting element of the dummy pixel.

4. The display device of claim 2, wherein the signal controller corrects the input image signal based on transition of a threshold voltage of the driving transistor with time to correct the input image signal.

5. The display device of claim 4, wherein
the sensing lines transmit a sensed data signal from the display pixel to the data driver, and
the sensed data signal comprises a first sensed data signal.

6. The display device of claim 5, wherein the signal controller comprises:
a first calculator to calculate the threshold voltage of the driving transistor based on the first sensed data signal; and
a first frame memory to store the threshold voltage of the driving transistor.

7. The display device of claim 6, wherein the signal controller further comprises an image signal corrector to correct the input image signal based on the transition of the threshold voltage of the light emitting element with time and the threshold voltage of the driving transistor with time.

8. The display device of claim 2, wherein the data driver comprises a basic circuit portion and a switching circuit portion.

9. The display device of claim 8, wherein the basic circuit portion comprises:
a digital-to-analog converter to convert the output image signal into the image data voltage; and
an analog-to-digital converter to receive the sensed data signals from the display pixel and convert the sensed data signals.

10. The display device of claim 9, wherein the switching circuit portion comprises:
a first switch to connect and disconnect the second switching transistor and a ground voltage;
a second switch to connect and disconnect the second switching transistor and a reference current source;
a third switch to connect and disconnect the first switching transistor and a first reference voltage;
a fourth switch to connect and disconnect the data line and the digital-to-analog converter;
a fifth switch to connect and disconnect the first switching transistor and a reverse bias voltage;
a sixth switch to connect and disconnect the sensing line and a precharge voltage;
a seventh switch to connect and disconnect the first switching transistor and a second reference voltage; and
an eighth switch to connect and disconnect the sensing line and the analog-to-digital converter.

11. The display device of claim 10, wherein the first reference voltage is lower than the threshold voltage of the driving transistor, and the second reference voltage is higher than the threshold voltage of the driving transistor.

12. The display device of claim 2, further comprising a fourth switching transistor connected to a control terminal of the driving transistor and to a power source.

13. The display device of claim 12, wherein the power source is applied with a first reference voltage or a second reference voltage.

14. The display device of claim 13, wherein the data driver comprises a basic circuit portion and a switching circuit portion.

15. The display device of claim 14, wherein the basic circuit portion comprises:
a digital-to-analog converter to convert the output image signal into the image data voltage; and
an analog-to-digital converter to convert the sensed data signal from the display pixel and convert the sensed data signal.

16. The display device of claim 15, wherein the switching circuit portion comprises:
a first switch to connect and disconnect the second switching transistor and a ground voltage;
a second switch to connect and disconnect the second switching transistor and a reference current source;
a third switch to connect and disconnect the data line and the digital-to-analog converter;
a fourth switch to connect and disconnect the first switching transistor and a reverse bias voltage;
a fifth switch to connect and disconnect the sensing line and a precharge voltage; and
a sixth switch to connect and disconnect the sensing line and the analog-to-digital converter.

17. The display device of claim 16, wherein the first reference voltage is lower than the threshold voltage of the driving transistor, and the second reference voltage is higher than the threshold voltage of the driving transistor.

18. The display device of claim 12, wherein the first switching transistor, the second switching transistor, the third switching transistor, and the fourth switching transistor is an n-channel field effect transistor.

19. The display device of claim 1, further comprising a signal controller to output the output image signal by correcting the input image signal based on transition of a threshold voltage of the driving transistor with time.

20. The display device of claim 1, wherein the driving transistor is an n-channel field effect transistor.

21. A driving method of a display device comprising a light-emitting element, a capacitor, and a driving transistor connected to the capacitor, the driving transistor comprising a control terminal, an input terminal, and an output terminal, the method comprising:
connecting an anode terminal of the light-emitting element with a reference current source;
sensing a voltage of the anode terminal of the light-emitting element; and
calculating a transition degree of a threshold voltage of the light-emitting element by comparing a voltage of the anode terminal of the light-emitting element with a reference anode voltage.

22. The driving method of claim 21, wherein the reference anode voltage is an anode voltage of a light-emitting element disposed in a dummy pixel that is not used to display an image.

23. The driving method of claim 21, wherein said calculating a transition degree of a threshold voltage is performed before the display device is turned on.

24. The driving method of claim 21, wherein said calculating a transition degree of a threshold voltage is performed with the driving transistor turned off.

25. The driving method of claim 21, further comprising:
connecting the control terminal with a data voltage;
disconnecting the control terminal from the data voltage and connecting the light-emitting element with the output terminal;
disconnecting the light-emitting element from the output terminal;
applying a reference voltage that is lower than a threshold voltage of the driving transistor to the control terminal;
connecting the output electrode with a ground voltage and disconnecting the output electrode from the ground voltage;
sensing a voltage of the output electrode; and
calculating the threshold voltage of the driving transistor based on a voltage of the output electrode.

26. The driving method of claim 25, wherein the threshold voltage of the driving transistor is determined by subtracting the voltage of the output electrode from the reference voltage.

27. The driving method of claim 25, further comprising correcting an input image signal based on transition degrees of the threshold voltage of the driving transistor and a threshold voltage of the light-emitting element.

28. The driving method of claim 25, wherein the driving transistor is an n-channel thin film transistor.

29. The driving method of claim 25, wherein said calculating a threshold voltage of the driving transistor is performed at least one time per each frame.

30. A driving method of a display device comprising a sensing line and a display pixel having a light-emitting element, a capacitor, and a driving transistor connected to the capacitor, the driving transistor comprising a control terminal, an input terminal, and an output terminal, the method comprising:
connecting the control terminal with a data voltage and connecting the sensing line with a precharge voltage;
disconnecting the control terminal from the data voltage and connecting the light-emitting element with the output terminal;
disconnecting the light-emitting element from the output terminal;
sensing an anode voltage of the light-emitting element through the sensing line after the light-emitting element is disconnected from the output terminal; and
calculating a transition degree of a threshold voltage of the light-emitting element by comparing an anode voltage of the light-emitting element with a reference anode voltage.

31. The driving method of claim 30, wherein the reference anode voltage is an anode voltage of a light-emitting element disposed in a dummy pixel that is not used to display an image.

32. The driving method of claim 31, further comprising correcting an input image signal based on a transition degree of the threshold voltage of the light emitting element.

33. The driving method of claim 30, wherein the driving transistor is an n-channel thin film transistor.

34. The driving method of claim 30, wherein said calculating a transition degree of a threshold voltage is performed at least one time per each frame.

35. A driving method of a display device comprising a plurality of first display pixels each having a first light-emitting element, a first capacitor, and a first driving transistor connected to the first capacitor, the first driving transistor having a first control terminal, a first input terminal, and a first output terminal, the method comprising:
connecting the first control terminal with a data voltage;
disconnecting the first control terminal from the data voltage and connecting the first light-emitting element with the first output terminal;
connecting the first light-emitting element with the first output terminal;
applying a reference voltage that is lower than a threshold voltage of the first driving transistor to the first control terminal;
connecting the first output electrode with a ground voltage and disconnecting the first output electrode from the ground voltage;
sensing a voltage of the first output electrode; and
calculating a threshold voltage of the first driving transistor based on a voltage of the first output electrode.

36. The driving method of claim 35, wherein the display device further comprises a plurality of second display pixels each having a second light-emitting element, a second capacitor, and a second driving transistor connected to the second capacitor, the second driving transistor comprising a second control terminal, a second input terminal, and a second output terminal, the method further comprising:
connecting the second control terminal with a data voltage;
disconnecting the second control terminal from the data voltage and connecting the second light-emitting element to the output terminal;
disconnecting the second light-emitting element from the second output terminal; and
applying a reverse bias voltage to the second control terminal.

37. The driving method of claim 36, wherein the reverse bias voltage has an opposite polarity to that of the data voltage.

38. The driving method of claim 36, wherein said calculating a transition degree of a threshold voltage and said applying a reverse bias voltage are performed simultaneously.

39. The driving method of claim 36, wherein said calculating a transition degree of a threshold voltage and said applying a reverse bias voltage are performed at least one time per each frame.

40. The driving method of claim 36, wherein the first display pixel and the second display pixel are disposed at the same pixel row.

41. The driving method of claim 36, wherein the driving transistor is an n-channel thin film transistor.
